(19) United States
(12) Patent Application Publication
(10) Pub. No.: US 2016/0355947 A1
(43) Pub. Date: Dec. 8, 2016

(54) Susceptor Heating For Epitaxial Growth Process

(71) Applicant: Sensor Electronic Technology, Inc., Columbia, SC (US)

(72) Inventors: Alexander Dobrinsky, Loudonville, NY (US); Michael Shur, Latham, NY (US)

(73) Assignee: Sensor Electronic Technology, Inc., Columbia, SC (US)

(21) Appl. No.: 15/173,660

(22) Filed: Jun. 5, 2016

Related U.S. Application Data
(60) Provisional application No. 62/171,341, filed on Jun. 5, 2015.

(51) Int. Cl. C30B 25/16; C30B 25/12; C23C 16/458; C23C 16/46; C23C 16/455; C23C 16/52; C30B 25/10; C30B 25/14

(52) U.S. Cl. CPC C30B 25/16; C30B 25/10; C30B 25/12; C30B 25/14; C23C 16/46; C23C 16/45565; C23C 16/52; C23C 16/4582

(57) ABSTRACT

An approach for heating a susceptor during an epitaxial growth process of semiconductor layers in an epitaxial growth chamber is described. A main heating unit heats a region of the susceptor supporting a wafer. An auxiliary heating unit supports the main heating unit in heating the susceptor when the temperature distribution over the surface of the wafer fails to satisfy a target temperature distribution. The control unit monitors the temperature distribution over the surface of the wafer while the susceptor is heated by both the main heating unit and the auxiliary heating unit and adjusts at least one of a multitude of operating parameters for the auxiliary heating unit in response to determining that the temperature distribution over the surface of the wafer while the susceptor is heated by the main heating unit and the auxiliary heating unit is failing to satisfy the target temperature distribution.

### REFERENCE TO RELATED APPLICATIONS

The present patent application claims the benefit of U.S. Provisional Application No. 62/171,341, which was filed on 5 Jun. 2015; and which is hereby incorporated by reference.

### TECHNICAL FIELD

The present invention relates generally to epitaxial film deposition, and more particularly, to heating a susceptor supporting a wafer that is undergoing an epitaxial growth process of semiconductor layers in an epitaxial growth chamber.

### BACKGROUND ART

During a typical epitaxial growth process, a substrate wafer may be directly placed on a susceptor of an epitaxial growth chamber. The susceptor, which can be mounted on a rotating shaft, provides support for the substrate wafer during the epitaxial growth of semiconductor layers thereon, while protecting the back side of the wafer. In addition, the susceptor facilitates uniform heating of the substrate wafer by a heating source during the epitaxial growth of semiconductor layers. Thermal uniformity of the substrate wafer during epitaxial growth processing is important, especially for epitaxially grown semiconductor materials such as group III nitride semiconductors that are frequently used in microprocessors, memory integrated circuits and other high density devices. A non-uniform temperature distribution on an epitaxially grown semiconductor layer may generate different chemical reaction rates at different portions of the epitaxially grown semiconductor layers on the substrate wafer. As a result, the material composition of the epitaxially grown semiconductor layers and the deposition rate of the layers may be altered by temperature inhomogeneities arising from the non-uniform temperature distribution. This can cause the epitaxially grown semiconductor layers to be non-uniform across the substrate wafer. In extreme cases, the substrate wafer can bow enough to crack or break, damaging or ruining the epitaxially grown semiconductor layers.

Heating sources, such as inductive heating coils, resistive heating coils or lamps, are commonly employed as a main heating source to heat a substrate wafer to a predetermined temperature set point during a typical epitaxial growth process. However, it is difficult to precisely control the temperature distribution imparted from these heating sources onto the substrate wafer. Quite often, the temperature distribution generated from these heating sources can be different from a target temperature specified for the epitaxial growth process. This can lead to epitaxially grown semiconductor layers having a non-uniform temperature distribution which can damage or ruin the grown semiconductor layers.

### SUMMARY OF THE INVENTION

This Summary Of The Invention introduces a selection of certain concepts in a brief form that are further described below in the Detailed Description Of The Invention. It is not intended to exclusively identify key features or essential features of the claimed subject matter set forth in the Claims, nor is it intended as an aid in determining the scope of the claimed subject matter.

Aspects of the present invention are directed to using an auxiliary heating unit in conjunction with a main heating unit to attain a substantially uniform temperature distribution during epitaxial growth of semiconductor layers, leading to layers having improved uniformity, and thus better quality, performance and yield. The auxiliary heating unit, which can be of a lower power than the main heating unit, can include a resistive heating element, an infrared heating system, an infrared emitter detector, and/or a focused heating infrared auxiliary source. A temperature sensor, such as a pyrometer, can sense the temperature of a surface of a wafer on a wafer carrier, such as a susceptor, while the wafer is being heated by the main heating unit during an epitaxial growth process.

A control unit can determine the temperature distribution over a region of the surface of the wafer while the wafer is being heated by the main heating unit in accordance with the temperature signals. The control unit can initiate operation of the auxiliary heating unit in response to determining that the temperature distribution over the surface of the wafer carrier is varying from a target temperature distribution. In particular, the control unit can specify certain operating parameters of the auxiliary heating unit. Illustrative operating parameters include a radiation source intensity, a time duration of operating the radiation source embodied by the auxiliary heating unit, a direction and/or a pattern of radiation generated from the radiation source towards the surface of the region of the wafer carrier, etc. The control unit can monitor the temperature distribution over the surface of the wafer while the susceptor is heated by both the main heating unit and the auxiliary heating unit. If the control unit determines that the temperature distribution over the surface of the wafer while the susceptor is heated by the main heating unit and the auxiliary heating unit is failing to satisfy the target temperature distribution, the control unit can adjust at least one of the operating parameters for the main heating unit or the auxiliary heating unit.

By controlling the temperature of the epitaxially grown semiconductor layers in this manner, aspects of the present invention are able to more precisely control process parameters during an epitaxial growth process. The better control can reduce operation and process variations and improve the quality, performance, and/or yield of epitaxially grown semiconductor layers.

A first aspect of the invention provides a system, comprising: a wafer carrier; a main heating unit configured to heat a region within the wafer carrier; an auxiliary heating unit configured to support the main heating unit in heating the region of the wafer carrier; at least one temperature sensor configured to sense a temperature of the region of the wafer carrier while being heated and generate signal representations of the temperature; and a control unit configured to control heating of the wafer carrier by the main heating unit and the auxiliary heating unit as a function of the temperature at the region of wafer carrier, the control unit determining a temperature distribution over a surface of the region of the wafer carrier while heated by the main heating unit in accordance with the temperature signals, the control unit initiating operation of the auxiliary heating unit in response to determining that the temperature distribution over the surface of the region of the wafer carrier fails to satisfy a target temperature distribution.

A second aspect of the invention provides a system for an epitaxial growth process of semiconductor layers, comprising: a susceptor configured to support at least one wafer during the epitaxial growth process; a showerhead element configured to release gases towards the susceptor for epitaxially growing the semiconductor layers on the wafer; a main heating unit configured to heat a region of the susceptor supporting the wafer; an auxiliary heating unit configured to support the main heating unit in heating the region of the susceptor; at least one pyrometer configured to sense a temperature of a surface of the wafer supported by the susceptor while being heated and generate signal representations of the temperature; and a control unit configured to control heating of the susceptor by the main heating unit and the auxiliary heating unit as a function of the temperature at the surface of the wafer, the control unit determining a temperature distribution over the surface of the wafer while the susceptor is heated by the main heating unit in accordance with the temperature signals generated from the pyrometer, the control unit initiating operation of the auxiliary heating unit along with an already powered main heating unit in response to determining that the temperature distribution over the surface of the wafer fails to satisfy a target temperature distribution, the control unit monitoring the temperature distribution over the surface of the wafer while the susceptor is heated by both the main heating unit and the auxiliary heating unit, and the control unit adjusting at least one of a plurality of operating parameters for the auxiliary heating unit in response to determining that the temperature distribution over the surface of the wafer while the susceptor is heated by the main heating unit and the auxiliary heating unit is failing to satisfy the target temperature distribution.

A third aspect of the invention provides a method, comprising: heating a wafer on a wafer carrier with a main heating unit during an epitaxial growth process of semiconductor layers; obtaining temperature measurements from a surface of the wafer while being heated; determining a temperature distribution over the surface of the wafer while being heated by the main heating unit; determining whether the temperature distribution over the surface of the wafer carrier satisfies a target temperature distribution; initiating operation of an auxiliary heating unit to heat the wafer along with the main heating unit in response to determining that the temperature distribution over the surface of the wafer carrier fails to satisfy a target temperature distribution; monitoring the temperature distribution over the surface of the wafer while the wafer is heated by both the main heating unit and the auxiliary heating unit; and adjusting at least one of a plurality of operating parameters for the auxiliary heating unit in response to determining that the temperature distribution over the surface of the wafer while heated by the main heating unit and the auxiliary heating unit is failing to satisfy the target temperature distribution.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1A shows a schematic of an epitaxial growth chamber with an induction heating coil used to heat a susceptor according to the prior art, and FIG. 1B shows a typical non-uniform temperature distribution formed along a surface of the susceptor depicted in FIG. 1A.

FIG. 2A shows a schematic of an epitaxial growth chamber with a main heating unit and an auxiliary heating unit according to an embodiment, and FIG. 2B shows a substantially uniform temperature distribution formed along a surface of the susceptor depicted in FIG. 2A due to the auxiliary heating unit operating in conjunction with the main heating unit.

FIG. 3 shows a schematic of a resistive heating element that can be used as an auxiliary heating unit according to an embodiment.

FIG. 4 shows a schematic of an infrared heating system having a set of heat lamps and reflectors that can be used as an auxiliary heating unit according to an embodiment.

FIG. 5 shows a schematic of an auxiliary heating unit that can include an infrared heating system having a set of heat lamps and reflectors that generate a target heating profile of heating radiation that is diffusively directed to a wafer on a susceptor via an intermediate heating element according to an embodiment.

FIG. 6 shows a schematic of a focused heating infrared auxiliary source that can be used as the auxiliary heating unit according to an embodiment.

FIGS. 7A-7C show examples of temperature fluctuations that can be laterally achieved over a surface of a wafer by using the focused heating infrared auxiliary source of FIG. 6 according to an embodiment, while FIG. 7D shows an example of interference of several laser beams generated by the focused heating infrared auxiliary source of FIG. 6 that can produce the lateral temperature fluctuations illustrated in FIGS. 7A-7C.

FIG. 8 shows a graphical representation of the temperature fluctuations and the magnitude variation depicted in FIGS. 7A-7C as a function of time according to an embodiment.

FIG. 9 shows a schematic of an in-situ measurement unit that can be used in conjunction with a main heating unit and an auxiliary heating unit according to an embodiment.

FIG. 10 shows a more detailed schematic of a control unit that can be used to control a main heating unit, an auxiliary heating unit, a temperature sensor and an in-situ measurement unit in an epitaxial growth process to attain a target temperature distribution on a susceptor according to an embodiment.

FIG. 11 shows a schematic of an illustrative environment depicting the operation of the main heating unit, the auxiliary heating unit, the temperature sensor, the in-situ measurement unit, and the control unit for use with a susceptor supporting a wafer for epitaxial growth of semiconductor layers according to an embodiment.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention are directed to using an auxiliary heating unit in conjunction with a main power unit to attain a uniform temperature distribution during epitaxial growth of semiconductor layers. The auxiliary heating unit can include a resistive heating element, an infrared heating system, an infrared emitter detector, and/or a focused heating infrared auxiliary source. At least one temperature sensor, such as a pyrometer, can sense the temperature of a surface of a wafer located on a wafer carrier, such as a susceptor, while the wafer is being heated by the main heating unit that can include an induction coil.

A control unit can determine the temperature distribution over a region of the surface of the wafer while the wafer being heated by the main heating unit in accordance with the temperature signals generated from the temperature sensor. The control unit can initiate operation of an auxiliary heating unit along with an already powered main heating unit in response to determining that the temperature distribution over the surface of the wafer carrier is not accomplishing a target temperature distribution. In particular, the control unit can specify certain operating parameters of the auxiliary heating unit, such as a radiation source intensity, a time duration of operating the radiation source, a direction and/or a pattern of radiation generated from the radiation source towards the surface of the region of the wafer carrier, and/or the like. The control unit can monitor the temperature distribution over the surface of the wafer while the wafer carrier and corresponding wafer are heated by both the main heating unit and the auxiliary heating unit. If the control unit determines that the temperature distribution over the surface of the wafer while the susceptor is heated by the main heating unit and the auxiliary heating unit is failing to satisfy the target temperature distribution, the control unit can adjust at least one of the operating parameters for the main heating unit or the auxiliary heating unit.

By controlling the temperature of the epitaxially grown semiconductor layers in this manner, aspects of the present invention are able to adjust the temperature characteristics over the surface of the wafer that are generated by the main heating unit by utilizing the auxiliary heating unit to adjust the temperature at the surface of the wafer. In this manner, target temperature characteristics can be attained over the surface of the wafer. For example, the target temperature characteristics can include an essentially uniform temperature over the surface of the wafer. In one embodiment, the control unit can adjust various operating parameters of the auxiliary heating unit based on temperature signals generated from at least one temperature sensor located about the susceptor to generate heating radiation along with the radiation provided from the main heating unit, that can yield temperature characteristics at the surface of the wafer that satisfy the target temperature characteristics. Having the capability to constantly adjust the operating parameters as a function of the temperature detected at the surface enables various aspects of the present invention to more precisely control the temperature characteristics over the surface of the wafer, and thus, making it easier to yield epitaxially grown semiconductor layers according to specified temperature profiles, characteristics, distributions, and the like.

The various illustrative embodiments described herein are suitable for epitaxial growth processes that utilize chemical vapor deposition (CVD). However, it is understood that embodiments of the present invention are not meant to be limited to CVD. Those skilled in the art will appreciate that other types of depositions, such as metal oxide chemical vapor deposition (MOCVD), can have applicability with the various embodiments described herein.

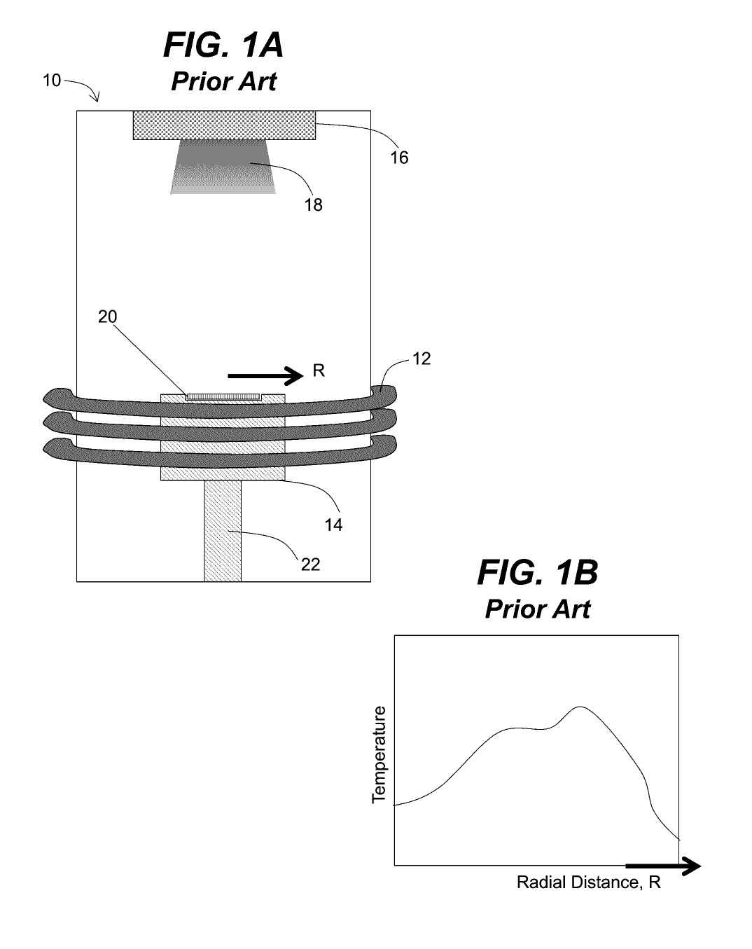

Referring now to the drawings, FIG. 1A shows a schematic of a reactor or an epitaxial growth chamber 10 with an induction heating coil 12 used to heat a susceptor 14 according to the prior art, while FIG. 1B shows a typical non-uniform temperature distribution formed along a surface of the susceptor depicted in FIG. 1A. As shown in FIG. 1A, the epitaxial growth chamber 10 further includes a showerhead element 16 located at a top portion of the chamber. The showerhead element 16 can release a flow of gases 18 towards a substrate wafer 20 located in a top region of the susceptor 14 during an epitaxial growth process in which semiconductor layers such as group III nitride semiconductor layers are epitaxially grown. In one embodiment, the epitaxial growth of group III nitride semiconductor layer can include an AlₓIn_{y}B_{z}Ga_{1-x-y-z}N semiconductor alloy with 0<x<1, 0<y<1, 0<z<1, 0<1−x−y−z<1. The gases released from the showerhead element 16 that can grow group III nitride semiconductor layers can include, but are not limited to, NH₃, H₂, and metalorganic gases.

During the epitaxial growth process, the induction heating coil 12 located about the susceptor 14 can heat the susceptor while it rotates about a shaft 22. The susceptor 14 can include material such as alumina, steel and any other elements capable of withstanding temperatures of about 2000K without affecting the gas dynamics within the chamber 10. The induction heating coil 12, can be water-cooled induction coils, capable of operating at about 20-40 kHz at currents of 1000-10000 Amperes. In some examples of semiconductor growth of group III nitride semiconductor layers, temperatures in the chamber 10 over the surface of the wafer 20 supported by the susceptor 14 can range from about 800° C. to about 1600° C.

Susceptors heated by heating elements such as induction coils are susceptible to non-uniform heating. This can result in regions of the susceptors, such as the part that supports the wafer, to have a non-uniform temperature distribution. As a result, the material composition of the epitaxially grown semiconductor layers and the deposition rate of the layers may be altered by temperature inhomogeneities arising from the non-uniform temperature distribution. This can cause the epitaxially grown semiconductor layers to be non-uniform across the substrate wafer. In extreme cases, the substrate wafer can bow enough to crack or break, thus damaging or ruining the epitaxially grown semiconductor layers.

FIG. 1B shows an example of a typical non-uniform temperature distribution formed along a surface of the susceptor 14 depicted in FIG. 1A where the wafer 20 is located. As shown in FIG. 1B, the temperature distribution is not uniform along the surface of the susceptor 14 in a radial direction R. This non-uniform temperature distribution along the radial direction R is due to the induction heating coil 12.

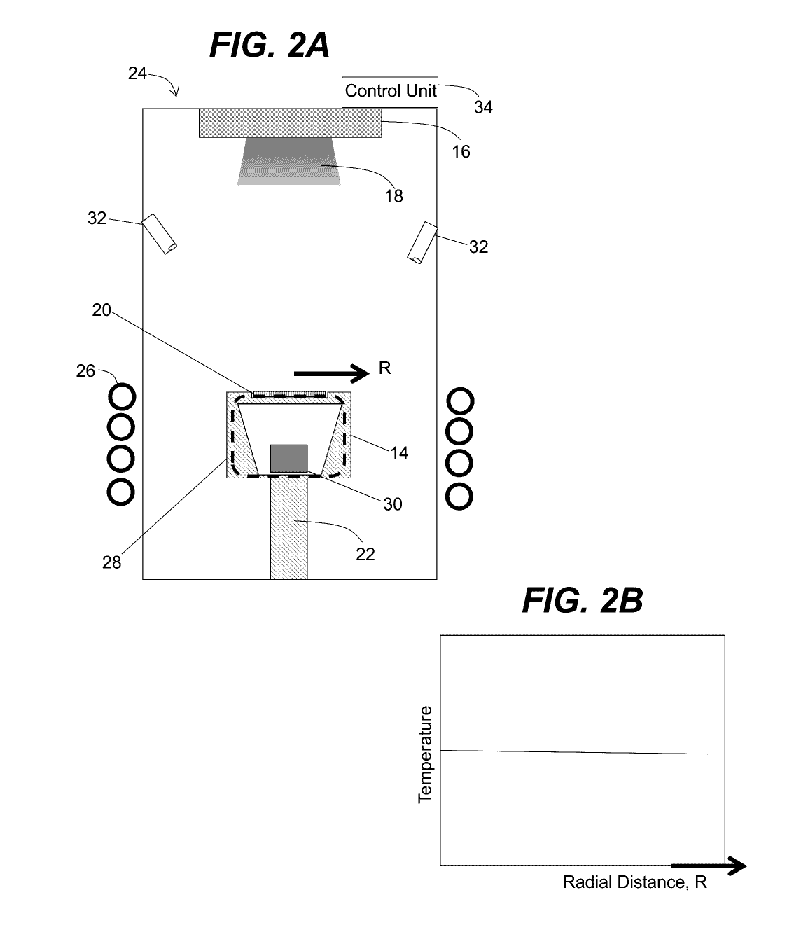

FIG. 2A shows a schematic of an epitaxial growth chamber 24 with a main heating unit 26 and an auxiliary heating unit 28 that are configured to heat a region of a wafer carrier in the form of the susceptor 14 according to an embodiment. In particular, the main heating unit 26, which can be any one of a number of heating sources, is configured to heat the region of the susceptor 14 that includes the wafer 20. Although not shown, it is understood that in this embodiment and others described herein, the susceptor can support multiple wafers for growth of semiconductor layers. In one embodiment, the main heating unit 26 can comprise an induction heating unit formed of induction coils located about the susceptor 14. Other examples of heating sources that are suitable for use as the sole main heating source can include, but are not limited to, resistive heaters, radio frequency inductive heaters, lamps, lamp banks and/or the like.

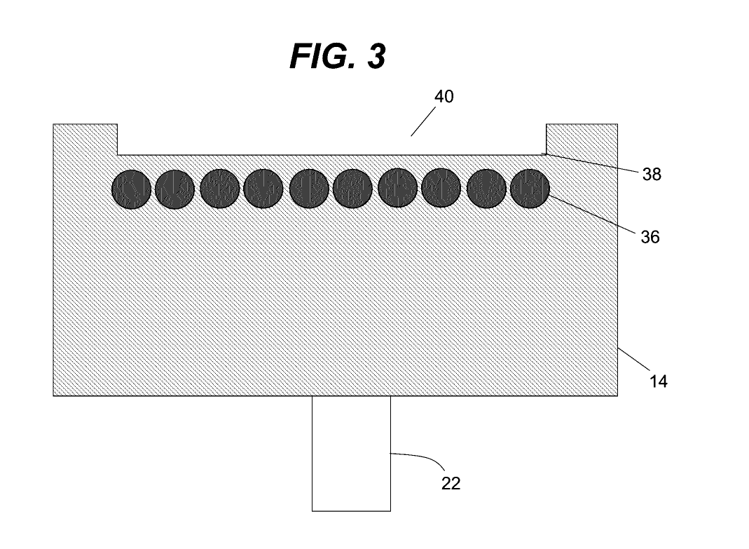

The auxiliary heating unit 28 is configured to support the main heating unit 26 in heating the region of the susceptor 14 that includes the wafer 20. As shown in FIG. 2A, the auxiliary heating unit 28 can be integrated within the susceptor 14 underneath the surface of the region in which the wafer 20 is placed. Although the auxiliary heating unit 28 is incorporated within the susceptor 14, it is understood that it is possible to have some or all of the components of the auxiliary heating unit 28 located on the exterior of the susceptor either above or below the surface in which the wafer 20 is placed. In one embodiment, the auxiliary heating unit 28 can include a heat lamp 30 that is configured to direct radiation toward backside of the surface of the susceptor 14 supporting the wafer 20. The auxiliary heating unit 28 can include a number of other heating sources that can operate in conjunction with the main heating unit 26 to ensure that a uniform temperature distribution is provided over the surface of the wafer 20. Examples of other heating sources that are suitable for use as the auxiliary heating unit 28 include, but are not limited to, resistive heaters, inductive coils, radio frequency inductive heaters, lamps, lamp banks, infrared lamps, infrared light emitting diodes (LEDs), infrared heating systems, lasers, focused heating infrared auxiliary sources, and the like. Various embodiments of auxiliary heating units which include some of these heating sources are described herein with respect to FIGS. 3-6 and 9.

The epitaxial growth chamber 24 of FIG. 2A can also include at least one temperature sensor 32 configured to sense a temperature of the region of the susceptor 14 supporting the wafer 20 while being heated and to generate signal representations of the temperature. Although not shown for sake of clarity, additional temperature sensors 32 can deployed about the chamber 24 to obtain temperature measurements in the portions of the chamber and generate signal representations of the measured temperature values. For example, other temperature sensors can be located below the susceptor 14 and/or off to the side of the susceptor. One skilled in the art will appreciate that there are many possible variations, alternatives and modifications to the number, location and orientation of the temperature sensors 32. In one embodiment, the temperature sensors 32 can include pyrometers. It is understood that other types of temperature sensors, such as thermocouples, can be used to obtain temperature measurements within the epitaxial growth chamber 24 in a location that can include the region of the susceptor 14 that supports the wafer 20. Furthermore, it is possible to utilize combinations of these various types of temperature sensors. Embodiments of the present invention are not limited to using only one type of temperature sensor.

As shown in FIG. 2A, the epitaxial growth chamber 24 can also include a control unit 34 that is configured to control heating of the susceptor 14 and the wafer 20, supported by the susceptor 14, by the main heating unit 26 and the auxiliary heating unit 28 as a function of the temperature measured by the temperature sensors 32. In one embodiment, the control unit 34 determines a temperature distribution over the surface of the wafer 20 while the susceptor 14 is heated by the main heating unit 26 in accordance with the temperature signals generated from the temperature sensors 32. The control unit 34 can initiate operation of the auxiliary heating unit 28 along with an already powered main heating unit 26 in response to determining that the temperature distribution over the surface of the wafer 20 fails to satisfy a target temperature distribution. The control unit 34 can also monitor the temperature distribution over the surface of the wafer 20 while the susceptor 14 is heated by both the main heating unit 26 and the auxiliary heating unit 28.

The control unit 34 can adjust at least one of a plurality of operating parameters for the auxiliary heating unit in response to determining that the temperature distribution over the surface of the wafer 20 while the susceptor 14 is heated by the main heating unit 26 and the auxiliary heating unit 28 is failing to satisfy the target temperature distribution. The plurality of operating parameters for the auxiliary heating unit 28 can comprise a radiation source intensity, a time duration of operating the radiation source that is associated with the auxiliary heating unit, and a direction and a pattern of radiation generated from the radiation source towards the surface of the region of the susceptor 14 supporting the wafer 20. In one embodiment, the control unit 34 can adjust one or more of these parameters in accordance to the flow rate of the gases released in the chamber 24 by the showerhead element 16. Further details of these operations and others that are performed by the control unit 34 in controlling the temperature over the surface of the wafer 20 and the susceptor 14 are described herein.

By having the control unit 34 control the temperature of the epitaxially grown semiconductor layers in this manner, it is possible to adjust the temperature characteristics over the surface of the wafer 20 that are generated by the main heating unit 26 and the auxiliary heating unit 28 and epitaxially grow semiconductor layers on the wafer that satisfy predetermined target temperature characteristics, making it easier to yield epitaxially grown semiconductor layers according to specified temperature profiles, characteristics, distributions, and the like. FIG. 2B shows an example of target temperature characteristics which comprises a uniform temperature distribution that is formed over a surface of the susceptor 14 depicted in FIG. 2A where it is heated by the main heating unit 26 and the auxiliary heating unit 28. As shown in FIG. 2B, the temperature distribution is uniform along the surface of the susceptor 14 in a radial direction R. This uniform temperature distribution along the radial direction R is due to the main heating unit 26 and the auxiliary heating unit 28 being precisely controlled by the control unit 34 as a function of the temperature measurements provided by the temperature sensor 32. In one embodiment, the target temperature distribution over the surface of the region of the susceptor 14 can have a variation of at most 20 degrees.

FIG. 3 shows a schematic of a resistive heating element 36 that can be used as an auxiliary heating unit according to an embodiment. As shown in FIG. 3, the resistive heating element 36 can be located underneath a surface 38 of a region 40 of the susceptor 14 that supports a wafer or a batch of wafers during an epitaxial growth of semiconductor layers. For sake of clarity, the main heating unit 26 is not shown in FIG. 3. In one embodiment, the resistive heating element 36 can include a set of resistive coils. Unless otherwise noted, the term “set” means one or more (i.e., at least one). These coils can be arranged underneath the surface 38 of the region 40 of the susceptor 14. In one embodiment, the coils can be arranged underneath the surface 38 of the susceptor 14 to form, as an example, a mesh or a spiral member. The number of coils that are arranged underneath the surface 38 of the region 40 can vary. For example, the number of coils can span the whole spacing of the region as shown by the number of resistive heating elements depicted in FIG. 3. However, it is understood that the number of coils can be less than that depicted in FIG. 3 by increasing the spacing there between. Also, it is possible to use larger sized coils that each generate more heating radiation, and thus, use fewer coils underneath the surface 38 of the region 40 of the susceptor 14.

The use of the resistive heating element 36 that includes resistive coils as the auxiliary heating unit can provide an amount of heating that is lower than the heating provided by the main heating unit. For example, in one embodiment, the auxiliary heating unit that includes resistive coils can typically generate no more than 20% of the total heating amount provided to the surface 38 of the region 40 of the susceptor 14 by both the auxiliary heating unit and the main heating unit. In this instance, since the auxiliary heating unit provides less heating, it can have different material and operational requirements as compared to a main heating unit, such as one formed from one of the various conventional main heating units that are currently in use.

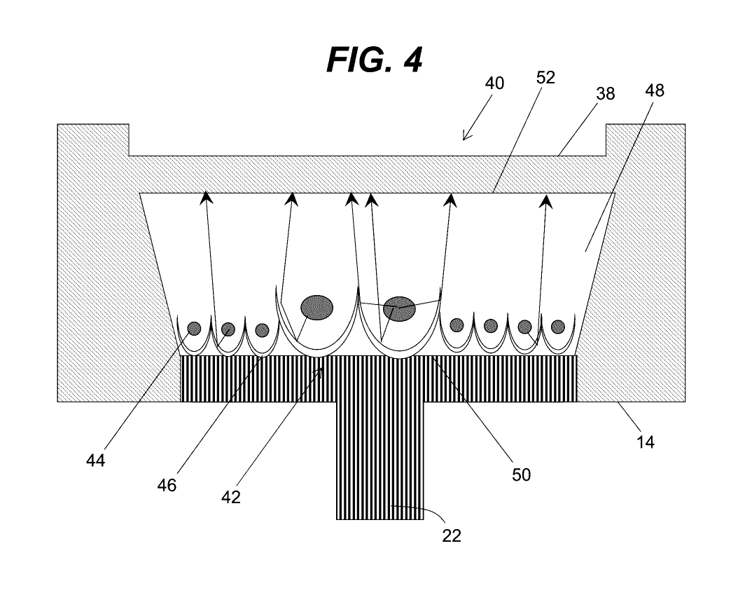

FIG. 4 shows a schematic of an infrared heating system 42 having a set of heat lamps 44 and reflectors 46 that can be used as an auxiliary heating unit according to an embodiment. In one embodiment, the heat lamps 44 and the reflectors 46 can be located underneath the surface 38 of the region 40 of the susceptor 14 in a cavity 48 of the susceptor 14. As shown in FIG. 4, the cavity 48 extends from a top region 50 of the shaft 22 to a top inner portion 52 of the susceptor 14 that is proximate the surface 38 of the region 40. In operation, the heat lamps 44 and the reflectors 46 can heat the surface 38 of the region 40 of the susceptor 14 and/or the back surface of the substrate wafer that can be supported by the susceptor. In particular, each heat lamp 44 in the set of heat lamps generates heating radiation, while a corresponding reflector 46 focuses the radiation to a targeted portion of the surface 38 of the region 40. The focused heating radiation generated from each heat lamp 44 and corresponding reflector 46 collectively form a target heating profile of heating radiation that is directed to the surface 38 of the region 40 of the susceptor 14 and/or the back surface of the substrate wafer. As used herein, a target heating profile is a particular spatial distribution of energy from the heat lamps 44 leading to a target temperature distribution over a surface of the susceptor 14.

In one embodiment, the set of heat lamps 44 can include tungsten based heaters, or any other lamps that can generate heat and light radiation resulting in heating. Examples of other lamps that can generate heat and light radiation resulting in heating can include, but are not limited to, infrared sources such as, for example, infrared lamps, and infrared LEDs.

In one embodiment the reflectors 46 can include parabolic reflective surfaces that can be designed to focus the heating radiation from the heat lamps 44 onto certain portions of the wafer or wafers supported by the susceptor 14 in accordance with the target heating profile. For example, consider a scenario in which the main heating unit is an induction heating unit utilizing induction coil(s), that generates a temperature profile that is lower in the center of the surface 38 of the region 40 of the susceptor 14. In this case, the reflectors 46 can be used to focus the heating radiation from the heat lamps 44 to the central portion of the susceptor 14.

The configuration of the heat lamps 44 and the reflectors 46 as used as an auxiliary heating unit for the susceptor 14 can vary. For example, as shown in FIG. 4, the set of heat lamps 44 can include a combination of different size heat lamps. In one embodiment, larger-sized heat lamps can be positioned in a central portion of the cavity 48 to direct a greater amount of the heating radiation to the central portion of the wafer(s) on the surface 38 of the region of the susceptor 14, while smaller-sized heat lamps can direct a lesser amount of radiation to the edge portion of the region 40. As shown in FIG. 4, the larger-sized heat lamps 44 can have corresponding larger-sized reflectors 46 to better focus the larger amount of heating radiation to a targeted area, while the smaller-sized heat lamps 44 can have smaller sized reflectors to focus the lesser amount of radiation to another area of the surface 38. Although FIG. 4, shows that each heat lamp 44 has a corresponding reflector 46 to focus the heating radiation to the surface 38 of the region 40 of the susceptor 14, it is understood that it is not necessary that all of the heat lamps have a corresponding reflector. For example, some of the heat lamps 44 that are situated on an outer periphery of the arrangement of the set of heat lamps that can direct heating radiation to the outer portion of the region 40 of the susceptor 14 may not need to have focused radiation due to the lack of any wafers being located there or that any epitaxial growth of semiconductor layers is desired at that location. Furthermore, it is understood that heat lamps 44 can be arranged in the susceptor 14 in any two dimensional pattern, such as a two-dimensional grid, hexagonal pattern, concentric circular pattern, and/or the like.

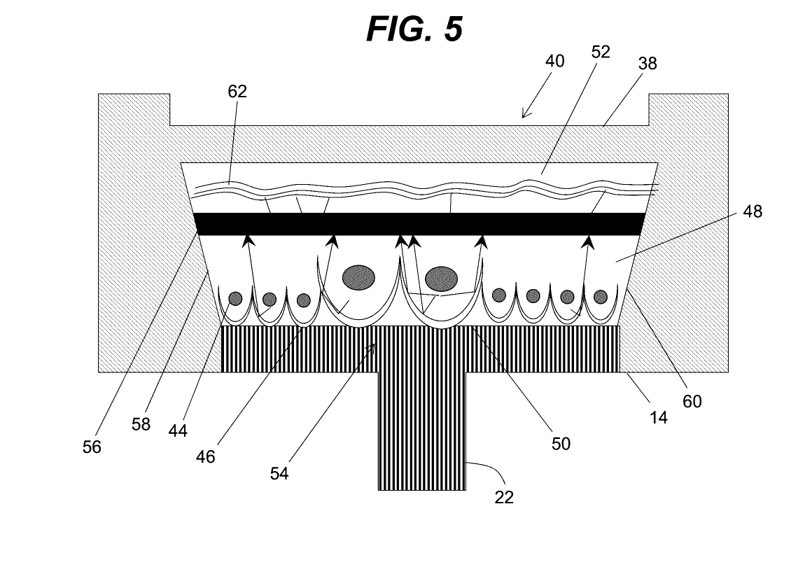

FIG. 5 shows a schematic of an alternative infrared heating system that can be used as an auxiliary heating unit according to an embodiment. In particular, FIG. 5 shows a schematic of an infrared heating system 54 having a set of heat lamps 44 and reflectors 46 that can generate a target heating profile of heating radiation that is diffusively directed to the surface 38 of the region 40 of the susceptor 14 via an intermediate heating element 56 that can be connected or disconnected from the susceptor 14. In one embodiment, the intermediate heating element 56 is a conductive member or element that can include, but is not limited to, materials such as tungsten. As shown in FIG. 5, the intermediate heating element 56 can be located in the cavity 48 between the top region 50 of the shaft 22 and the top inner portion 52 of the susceptor 14 that is proximate the surface 38 of the region 40. In one embodiment, the intermediate heating element 56 can extend laterally from a first side 58 of the cavity 48 to an opposing second side 60 of the cavity. In one embodiment, the intermediate heating element 56 can be centrally located within the cavity 48. Placing the intermediate heating element 56 in such a location can modify the distribution of heat over a susceptor 14 and/or provide additional heating that cannot be achieved with heat lamp(s) 44. It is understood that the intermediate heating element 56 can be situated in other locations within the cavity 48.

In operation, the heat lamps 44 and the reflectors 46 can heat the intermediate heating element 56 according to the target heating profile configured by the heat lamps and corresponding reflectors. The intermediate heating element 56 can in turn heat the surface 38 of the region 40 of the susceptor 14 and/or the back surface of any wafers placed in this region through light radiation or conduction, or through the use of gas convection 62 that is diffusively transmitted from the intermediate heating element. In this manner, the intermediate heating element 56 can heat the surface 38 of the region 40 of the susceptor 14 and/or the back surface of any wafers according to the target heating profile, while allowing this auxiliary heating system to be sufficiently removed from the region 40 of the susceptor 14, which is also being heated by induction via the main heating unit. A benefit of having the auxiliary heating system sufficiently removed from the region 40 of the susceptor 14 heated by the main heating unit is an improvement of the uniformity and control of temperature profile over the surface 38 of the susceptor 14.

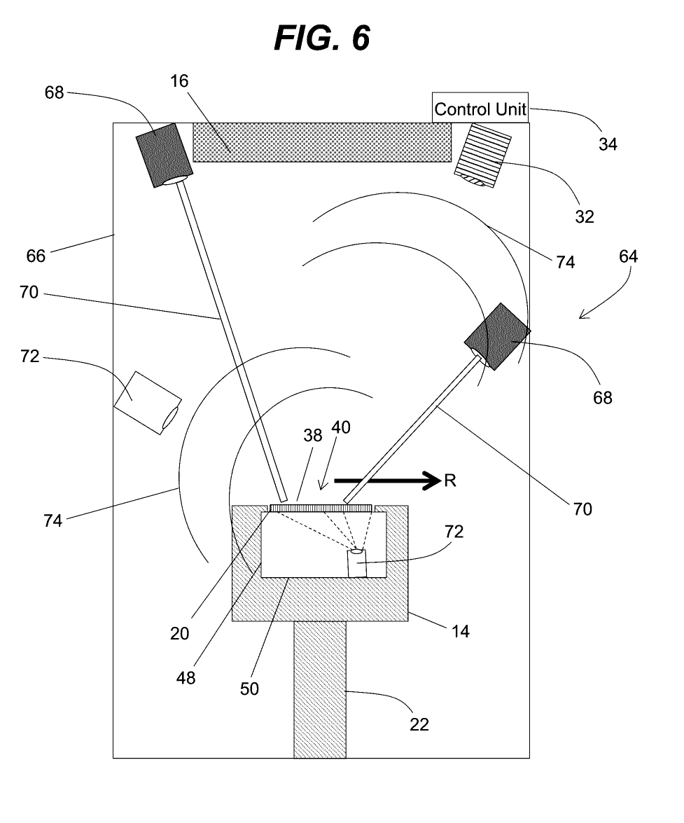

FIG. 6 shows a schematic of a focused heating infrared auxiliary source 64 that can be used as the auxiliary heating unit with an epitaxial growth chamber 66 according to an embodiment. In one embodiment, the focused heating infrared auxiliary source 64 is configured to direct infrared radiation over different areas of the surface 38 of the region 40 of the susceptor 14 that supports the wafer 20. As shown in FIG. 6, the focused heating infrared auxiliary source 64 can include at least one infrared laser 68. In one embodiment, the infrared lasers 68 can direct heating radiation 70 to different portions of the surface 38 of the region 40 supporting the wafer 20 and heat these portions by utilizing the motion of the infrared beam embodied by the radiation 70. In an embodiment, one laser 68 can be located in a top portion of the epitaxial growth chamber 66 near the showerhead element 16, while another laser 68 can be located in a middle portion of the chamber at a side opposite the first laser. In this manner, the lasers 68 can operate in conjunction to introduce lateral fluctuations to the semiconductor layers epitaxially grown on the wafer 20. As explained below in more detail, the lateral fluctuations can impart temperature fluctuations laterally over the surface of the wafer 20. The lateral fluctuations can comprise patterns of: grids of lines of varying thickness and intensity. In this manner, the lateral temperature fluctuations can induce compositional fluctuations within the semiconductor layers epitaxially grown on the wafer 20 through diffusion, wherein the compositional fluctuations for the semiconductor layers varies as a function of a temperature and a diffusion rate at a region of the semiconductor layers having the lateral temperature fluctuations.

The focused heating infrared auxiliary source 64 can also include at least one infrared lamp 72. The infrared lamps 72 can include, but are not limited to, infrared LEDs, incandescent heat lamps, and/or the like. In one embodiment, the infrared lamp 72 can direct heating radiation 74 to different portions of the surface 38 of the region 40 supporting the wafer 20. In an embodiment, one infrared lamp 72 can be located in a middle portion of the epitaxial growth chamber 66, while another infrared lamp 72 can be located in the cavity 48 of the susceptor 14 at the top portion 50 of the shaft 22. In this manner, each infrared lamp 72 is configured to direct heating radiation to different portions of the region 40 of the susceptor having the wafer 20. In particular, one infrared lamp 72 can direct heating radiation to a top surface of the wafer 20, while another infrared lamp can direct radiation to a backside of the wafer. Like the infrared lasers 68, the infrared lamps 72 can focus the radiation to specific locations on the wafer 20. In combination, the infrared lasers 68 and the infrared lamps 72 can operate in conjunction to provide a very fine type of heat radiation focusing that enables the semiconductor layers to be epitaxially grown according to a target heating profile.

It is understood that the focused heating infrared auxiliary source 64 is not meant to be limited to the number of infrared lasers 68 and infrared lamps 72 depicted in FIG. 6. There can be more or less than the two infrared lasers 68 and the two infrared lamps 72 shown in FIG. 6. Furthermore, the locations of the infrared lasers 68 and the infrared lamps 72 within the epitaxial growth chamber 66 can vary from what is illustrated in FIG. 6. For example, there can be multiple infrared lamps 72 within the cavity 48 of the susceptor, as well as multiple infrared lamps at different portions of the chamber 66 with each having a different height level with respect to the wafer 20 and the region 40 of the susceptor 14. In addition, the focused heating infrared auxiliary source 64 include only infrared lasers 68, or only infrared lamps 72, or as depicted in FIG. 6, combinations of both the infrared lasers 68 and the infrared lamps 72.

In one embodiment, the epitaxial growth chamber 66 can also include at least one temperature sensor 32 configured to sense a temperature of the region of the susceptor 14 supporting the wafer 20 while being heated by the focused heating infrared auxiliary source 64 and the main heating unit (not illustrated in FIG. 6) and generate signal representations of the temperature. Although only one temperature sensor 32 is depicted in FIG. 6, additional temperature sensors can be deployed about the chamber 66 to obtain temperature measurements in the portions of the chamber and generate signal representations of the measured temperature values provided by the focused heating infrared auxiliary source 64. It is understood that there are many possible variations, alternatives and modifications to the number, location and orientation of the temperature sensors 32.

In one embodiment, the temperature sensors 32 used with the focused heating infrared auxiliary source 64 can include a pyrometer. It is understood that other types of temperature sensors, such as a thermocouple, can be used to obtain temperature measurements within the epitaxial growth chamber 66 in a location that can include the region of the susceptor 14. Furthermore, it is possible to utilize combinations of these various types of temperature sensors and that embodiments of the present invention are not limited to using only one type of temperature sensor.

The control unit 34 is configured to control heating of the susceptor 14 and the wafer 20 supported by the susceptor by the main heating unit 26 and the focused heating infrared auxiliary source 64 as a function of the temperature measured by the temperature sensor 32. In one embodiment, the control unit 34 determines a temperature distribution over the surface of the wafer 20 while the susceptor 14 is heated by the main heating unit 26 in accordance with the temperature signals. The control unit 34 can initiate operation of the focused heating infrared auxiliary source 64 along with an already powered main heating unit 26 in response to determining that the temperature distribution over the surface of the wafer 20 fails to satisfy a target temperature distribution, and thus, provide the necessary amount of radiation in a focused manner to attain the target heating profile. The control unit 34 can also monitor the temperature distribution over the surface of the wafer 20 while the susceptor 14 is heated by both the main heating unit 26 and the focused heating infrared auxiliary source 64. In this manner, the control unit 34 can then adjust one of the aforementioned operating parameters for the auxiliary heating unit in response to determining that the temperature distribution over the surface of the wafer 20 while the susceptor is heated by the main heating unit 26 and the auxiliary heating unit 28 is failing to satisfy the target temperature distribution, and/or obtain the focused heating necessary for the target heating profile. In another embodiment, the control unit 34 can adjust one or more operating parameters of the main heating unit 26 in addition to the auxiliary heating unit 28. In this manner, the control unit 34 can provide comprehensive control of the temperature characteristics of the susceptor 14 and wafer 20.

In another embodiment, although not depicted in FIG. 6 for clarity, it is possible to have the focused heating infrared auxiliary source 64 and the temperature sensor 32 in the form of a single component. For example, the focused heating infrared auxiliary source 64 and the temperature sensor 32 can take the form of a solid-state device such as an infrared emitter detector. In this embodiment, the infrared emitter detector can operate periodically as an infrared emitter that directs infrared heating radiation to the surface 38 of the region 40 of the susceptor 14 supporting the wafer 20 and periodically as an infrared detector that detects the temperature at the region of the susceptor, and provides the signal representations of the temperature to the control unit 34. In this manner, the control unit 34 can adjust an infrared emission intensity of the infrared emitter detector and a time duration of operating the infrared emitter as a function of the temperature signals for obtaining the target temperature distribution that is directed to the wafer 20, to attain the desired epitaxially grown semiconductor layer.

In another embodiment, the control unit 34 can be configured to control the infrared lasers 68 and the infrared lamps 72. Furthermore, the control unit 34 can fluctuate the heating intensity directed to the wafer 20 with time, space (e.g., areas of heating), or both.

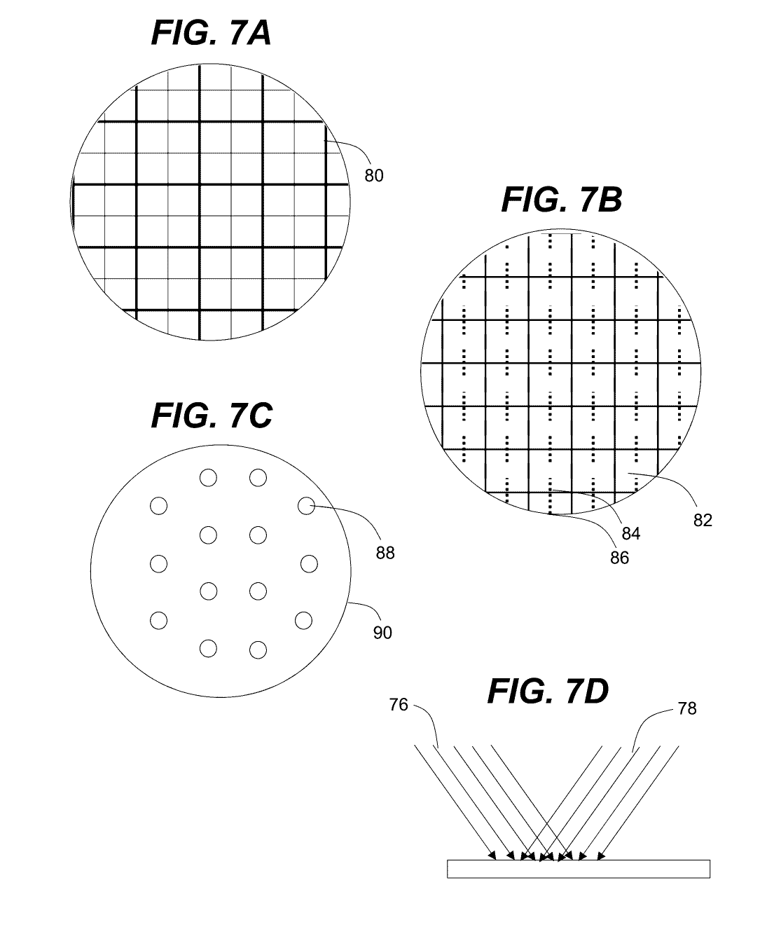

FIGS. 7A-7C show examples of temperature fluctuations that can be laterally achieved over the surface of a wafer by using the focused heating infrared auxiliary source of FIG. 6 according to an embodiment. FIG. 7D shows an example of interference of several laser beams generated by the focused heating infrared auxiliary source of FIG. 6 that can produce the lateral temperature fluctuations illustrated in FIGS. 7A-7C. In particular, the lateral temperature fluctuations depicted in FIGS. 7A-7C can be achieved by means of interference by laser beams 76 and 78 schematically shown in FIG. 7D. The resulting pattern generated by the interference of laser beams 76 and 78 can be a grid of lines of various thicknesses and intensity, with some of the patterns and lines as shown by reference elements 80, 82, 84, 86, 88 and 90 in FIGS. 7A-7C. In the drawings, the darker colors indicate regions with higher temperatures.

The examples of patterns and lines illustrated in FIGS. 7A-7C can be beneficial for controlling the lateral properties of the epitaxial grown semiconductor layers. For example, by altering the temperature throughout the layers the compositional fluctuations can be induced due to the different diffusion rates at different temperatures in different regions. A compositional fluctuation, such as for example, an AlₓIn_{y}B_{z}Ga_{1-x-y-z}N material can result in various improvements that can range from control of stress and strain in the lateral direction by controlling effective lattice constant, to controlling localization of electron-holes for recombination purposes. In particular, a pattern can be chosen with the distances between localization centers being closer than the dislocation density within the material. In addition, the pattern can be chosen with localization centers having a lateral area with a characteristic size being less than a distance between dislocations; wherein the characteristic size is calculated and defined as a square root of the lateral area. In any event, the localization center can result in heating a section of the film to higher temperatures as compared to the surrounding sections. Alternatively, the localization center can result in heating surrounding material to temperatures that are higher than the temperature of a particular section of the film.

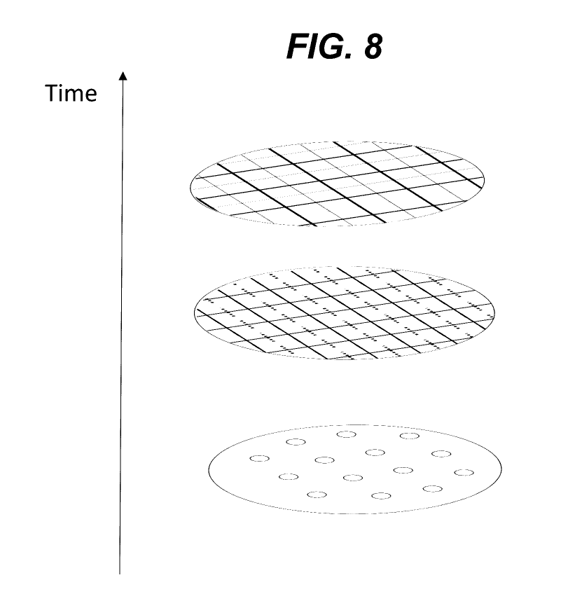

The various heating patterns and lines illustrated in FIGS. 7A-7C can be observed and understood as a function of time. For example, FIG. 8 shows a graphical representation of the temperature fluctuations and the magnitude variation depicted in FIGS. 7A-7C as a function of time according to an embodiment. In particular, FIG. 8 shows that the heating patterns and lines of FIGS. 7A-7C are changing in time. In this manner, the heating pattern timing can be correlated with the metalorganic flow pulses, and with pulses of other gases to create complex control for growth of semiconductor layers. Not only the heating pattern, but also the heating intensity of both the auxiliary heating unit and the main heating unit can be changed in time. Furthermore, the heating pattern/intensity can be adjusted based on the feedback from the temperature sensors (e.g., pyrometers) to the control unit.

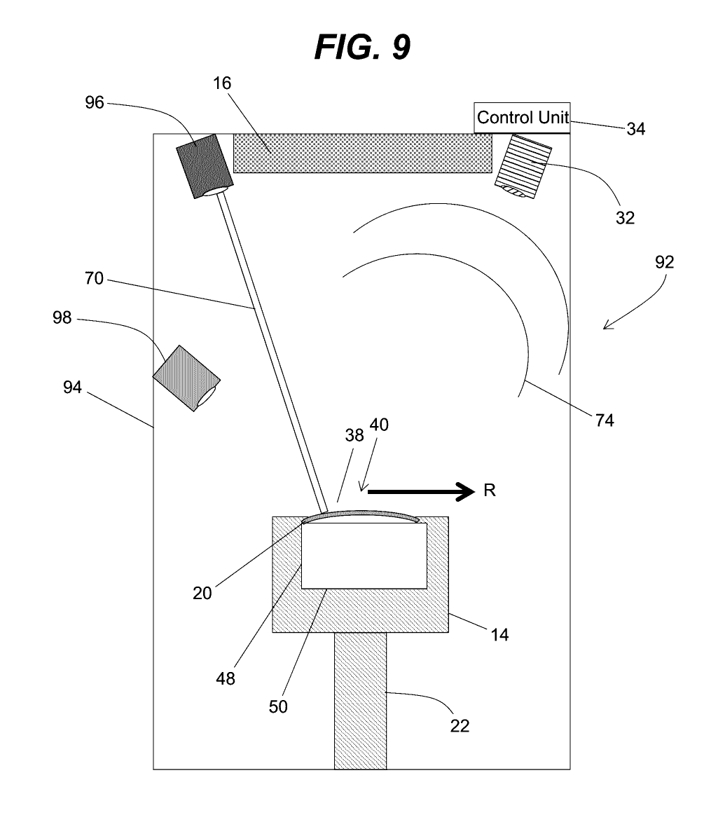

FIG. 9 shows a schematic of an in-situ measurement unit 92 that can be used in conjunction with a main heating unit and an auxiliary heating unit in an epitaxial growth chamber 94 according to an embodiment. Although not shown in FIG. 9, the in-situ measurement unit 92 can be used in conjunction with the main heating unit and any one of the aforementioned auxiliary heating units. In one embodiment, the in-situ measurement unit 92 is configured to obtain a plurality of measurements from the surface 38 of the region 40 of the susceptor 14 supporting the wafer 20 during the epitaxial growth of the semiconductor layers. As shown in FIG. 9, the in-situ measurement unit 92 can include at least one laser 96 used for measurements. In one embodiment, the laser 96 can direct heating radiation 70 to a portion of the surface 38 of the region 40 of the susceptor 14 supporting the wafer 20 and heat this portion by utilizing the motion of the beam embodied by the radiation 70. In an embodiment, the laser 96 can be located in a top portion of the epitaxial growth chamber 94 near the showerhead element 16. In this manner, the laser 96 can direct the radiation to a particular location on the surface of the wafer 20. In one embodiment, the radiation generated from the laser 96 can be in the form of a particular pattern. In another embodiment, the laser 96 can introduce lateral alloy inhomogeneities in an AlₓIn_{y}B_{z}Ga_{1-x-y-z}N semiconductor alloy by affecting the diffusion rate of precursors and the flow dynamics of precursor gases at different regions within the semiconductor layers that epitaxial grown in the chamber 94.

The in-situ measurement unit 92 can also include at least one optical detector 98. The optical detector 98 can include, but is not limited to, an infrared camera, a photodetector, and/or the like. In one embodiment, the optical detector 98 can obtain photoluminescence and/or cathodoluminescence measurements and generate signal representations of these measurement to the control unit 34. The control unit 34 can determine the presence of any lateral inhomogeneities on the semiconductor layers during the epitaxial growth process based on these measurements. With this information, the control unit 34 can then adjust the laser 96 direction and/or intensity to affect areas having inhomogeneities. In one embodiment, the control unit 34 can change one of the operating parameters associated with the laser 96. The operating parameters of the laser 96 can include, but are not limited to, the heating intensity, the duration that the laser directs radiation to the wafer 20, and the position and/or direction of the laser with respect to the wafer.

In one embodiment, the optical detector 98 can be used to obtain wafer bowing measurements of the wafer 20 during the epitaxial growth process and generate signal representations to the control unit 34. The control unit 34 can adjust the operation of the auxiliary heating unit to generate a heating radiation that imparts a predetermined amount bowing to the wafer 20 through the use of thermal expansion of the wafer. In particular, the control unit 34 can adjust the auxiliary heating unit as a function of the wafer bowing measurements obtained by the optical detector 98. For example, when bowing above a target value is detected, the heating can induce changes in the temperature of the semiconductor layers which, due to thermal expansion, affect the stresses within the layers resulting in changes to the bowing.

It is understood that the in-situ measurement unit 92 is not meant to be limited to only one laser 96 and one optical detector 98 as depicted in FIG. 9. More than one laser 96 and one optical detector 98 can be used in the chamber 94 shown in FIG. 9. Furthermore, the locations of the laser 96 and the optical detector 98 within the epitaxial growth chamber 94 can vary from what is illustrated in FIG. 9.

In one embodiment, the epitaxial growth chamber 94 can also include at least one temperature sensor 32 configured to sense a temperature of the region of the susceptor 14 supporting the wafer 20 while being heated by the main heating unit and the auxiliary heating unit (both not illustrated in FIG. 9), and while the in-situ measurement unit 92 operates to perform its intended functions. The temperature sensor 32 used with the in-situ measurement unit 92 can include a pyrometer, however, it is understood that other types of temperature sensors can be used. Although only one temperature sensor 32 is depicted in FIG. 9, additional temperature sensors can be deployed about the chamber 94 to obtain temperature measurements in the portions of the chamber and generate signal representations of the measured temperature values provided by the auxiliary heating unit. It is understood that there are many possible variations, alternatives and modifications to the number, location and orientation of the temperature sensor 32.

As described herein, the control unit 34 can use the temperature measurements from the temperature sensor 32 to control heating of the susceptor 14 and the wafer 20 supported by the main heating unit and the auxiliary heating unit as a function of the temperature measured by the temperature sensor 32. For example, the control unit 34 can determine a temperature distribution over the surface of the wafer 20 while heated alone by the main heating unit, or by both the main heating unit and the auxiliary heating unit. The control unit 34 can also monitor the temperature distribution over the surface of the wafer 20 while the susceptor 14 is heated by both the main heating unit and the auxiliary heating unit. The control unit 34 can then adjust one of the aforementioned operating parameters for the auxiliary heating unit or the main heating unit to ensure that a target temperature distribution is attained.

In another embodiment, the temperature sensor 32 can be used in conjunction with the in-situ measurement unit 92. For example, the control unit can measure bowing of the wafer to adjust a heating intensity of the main heating unit and/or the auxiliary heating unit.

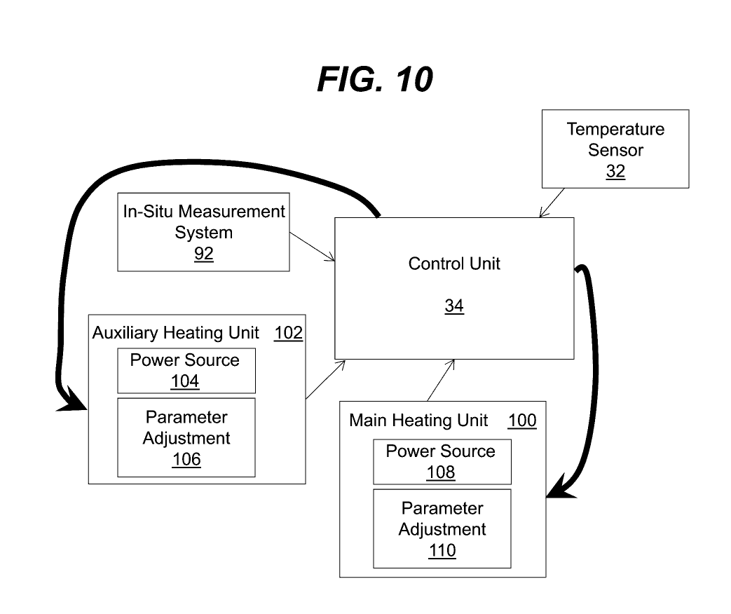

FIG. 10 shows a more detailed schematic of the control unit 34 that can be used to control a main heating unit 100, an auxiliary heating unit 102, a temperature sensor 32 and an in-situ measurement unit 92 in an epitaxial growth process to attain a target temperature distribution on a susceptor according to an embodiment. The auxiliary heating unit 102 can include any one of the auxiliary heating units described herein with respect to FIGS. 2A, 3, 4, 5, and 6, while the main heating unit 100 can be a conventional heating unit like those described herein. As shown in FIG. 10, the main heating unit 100 and the auxiliary heating unit 102 can include a power source 108 and 104, respectively, that enables each to generate heating radiation to a susceptor used in an epitaxial growth chamber. In addition, the main heating unit 100 and the auxiliary heating unit 102 can include a parameter adjustment component 110 and 106, respectively, that can be used to generate heating radiation at a predetermined intensity, duration, position, direction and pattern at a wafer or wafers supported by the susceptor. It is understood that the parameter adjustment components 106 and 110 can be used to adjust other parameters. For example, the parameter adjustment component 106 can adjust parameters of the auxiliary heating unit 102 that can include peak wavelength and light angular distribution. Another parameter that can be adjusted for the main heating unit 100 and the auxiliary heating unit 102 can include the time dependence of the intensity of different heating sources for both units.

The control unit 34 can control the temperature at the surface of the wafer supported by the susceptor in an epitaxial growth chamber during growth of semiconductor layers by first obtaining temperature measurements from the surface by the temperature sensor 32. In one embodiment, the temperature can include a pyrometer, however, it is understood that other types of temperature sensors can be used. The control unit 34 can then determine a temperature distribution over the surface of the wafer while being heated by the main heating unit 100. This step entails adjusting main and auxiliary heating elements to achieve a desired temperature distribution. Next, the control unit 34 can determine whether the temperature distribution over the surface of the wafer satisfies a target temperature distribution. If the control unit 34 determines that the temperature distribution over the surface of the wafer fails to satisfy a target temperature distribution, the control unit 34 can initiate operation of the auxiliary heating unit 102 to heat the wafer along with the main heating unit 100. Initiating operation of the auxiliary heating unit 102 can entail the control unit 34 specifying a plurality of operating parameters for the auxiliary heating unit 102 that are implemented by the parameter adjustment component 106. This step is coordinated with heating already being supplied by the main heating unit 100. In this manner, the control unit 34 can precisely control the main heating unit 100 and the auxiliary heating unit 102 to enable heating of the surface of the wafer to the target temperature distribution.

Other actions performed by the control unit 34 can include monitoring the temperature distribution over the surface of the wafer while it is heated by both the main heating unit 100 and the auxiliary heating unit 102. If the control unit 34 determines that the temperature distribution over the surface of the wafer while heated by the main heating unit and the auxiliary heating unit is failing to satisfy the target temperature distribution, then it can instruct the parameter adjustment component 106 of the auxiliary heating unit 102 and/or the parameter adjustment component 110 of the main heating unit 100 to adjust one or more of the aforementioned operating parameters to facilitate the target temperature distribution being attained at the surface of the wafer supported by the susceptor.

FIG. 9 shows that the control unit 34 can also interact with the in-situ measurement unit 92, which can take the form of the aforementioned modalities and operate in a similar manner. As mentioned above, the in-situ measurement unit 92 can obtain a plurality of measurements from the surface of the wafer during the epitaxial growth of the semiconductor layers on the wafer. In one embodiment, the in-situ measurement unit 92 can obtain photoluminescence and/or cathodoluminescence measurements, which the control unit 34 can be used to determine the presence of any lateral inhomogeneity on the semiconductor layers during the epitaxial growth process based on these measurements. In this manner, the control unit 34 can adjust the auxiliary heating laser to affect the inhomogeneities.

In another embodiment, the in-situ measurement unit 92 can obtain wafer bowing measurements of the wafer during the epitaxial growth process and generate signal representations to the control unit 34. The control unit 34 can then adjust the operation of the auxiliary heating unit 102 to generate a heating radiation that imparts a predetermined amount bowing to the wafer through the use of thermal expansion of the wafer.

In general, the in-situ measurement unit 92 can also interact with the control unit 34 to adjust the heating elements intensity, position, duration, orientation, and/or the like, to deliver a target temperature distribution over the susceptor surface.

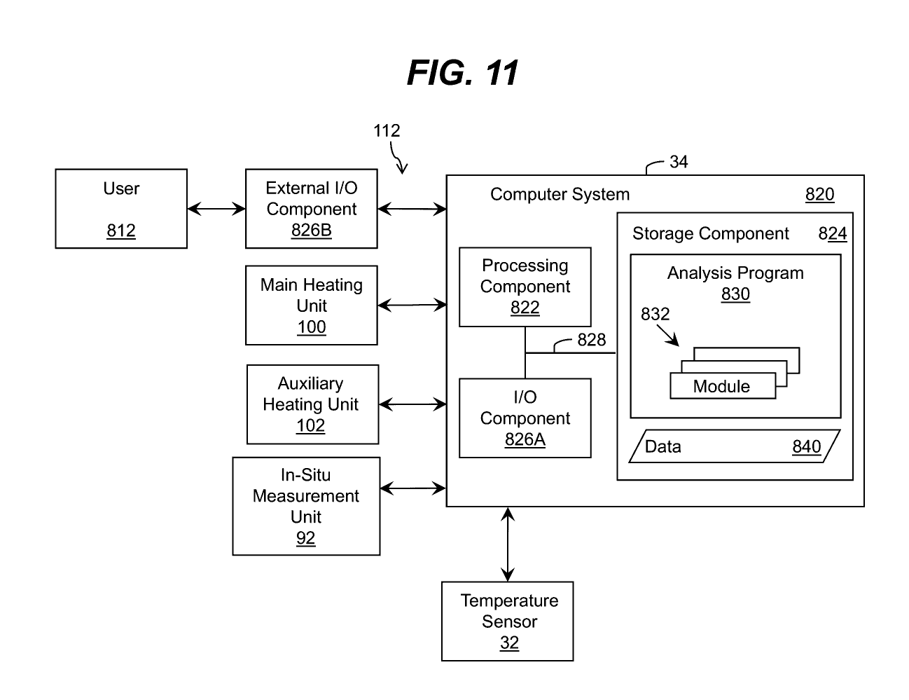

FIG. 11 shows a schematic of an illustrative environment 112 depicting the operation of the main heating unit 100, the auxiliary heating 102, the temperature sensor 32, the in-situ measurement unit 92, and the control unit 34 for use with precisely controlling a temperature distribution over a region of a susceptor supporting a wafer for epitaxial growth of semiconductor layers according to an embodiment. As depicted in FIG. 11, control unit 34 can be implemented as a computer system 820 including an analysis program 830, which makes the computer system 820 operable to manage the main heating unit 100, the auxiliary heating 102, the temperature sensor 32, and the in-situ measurement unit 92 in the manner described herein. In particular, the analysis program 830 can enable the computer system 820 to operate the main heating unit 100, the auxiliary heating 102, the temperature sensor 32, and the in-situ measurement unit 92 and process data corresponding to one or more attributes regarding these components, and/or an historical data stored as data 840. This data 840 can include, but is not limited to, spatial time dependent temperature maps of heated wafers, operating spatial time dependent temperature maps of heated wafers and grown wafer characteristics, and operating spatial time dependent temperature maps of the heated wafers, the grown wafer characteristics and means for data mining to correlate the wafer quality to the temperature growth regimes.

In an embodiment, during operation, the computer system 820 can acquire data from the temperature sensor 32 and/or the in-situ measurement unit 92 regarding one or more attributes of the wafer, the susceptor, the main heating unit 100 and/or the auxiliary heating unit 102, and generate data 840 for further processing. The computer system 820 can use the data 840 to control one or more aspects of the heating radiation generated by the main heating unit 100 and/or the auxiliary heating unit 102 during epitaxial growth of semiconductor layers.

Furthermore, one or more aspects of the operation of the main heating unit 100, the auxiliary heating unit 102 and/or the in-situ measurement unit 92 can be controlled or adjusted by a user 812 via an external I/O component 826B. The external I/O component 826B can include a touch screen that can selectively display user interface controls, such as control dials, which can enable the user 812 to adjust one or more of the operating parameters. In an embodiment, the external I/O component 826B could conceivably include a keyboard, a plurality of buttons, a joystick-like control mechanism, and/or the like, which can enable the user 812 to control one or more aspects of the operation of the main heating unit 100, the auxiliary heating unit 102 and/or the in-situ measurement unit 92. The external I/O component 826B also can include one or more output devices (e.g., an LED, a visual display, a speaker, and/or the like), which can be operated by the computer system 820 to indicate operational information to the user 812. For example, the output devices can include one or more LEDs used for example, for emitting a visual light for the user 812 regarding the temperature of the wafer(s) during an epitaxial growth process of semiconductor layers.

The computer system 820 is shown including a processing component 822 (e.g., one or more processors), a storage component 824 (e.g., a storage hierarchy), an input/output (I/O) component 826A (e.g., one or more I/O interfaces and/or devices), and a communications pathway 828. In general, the processing component 822 executes program code, such as the analysis program 830, which is at least partially fixed in the storage component 824. While executing program code, the processing component 822 can process data, which can result in reading and/or writing transformed data from/to the storage component 824 and/or the I/O component 826A for further processing. The pathway 828 provides a communications link between each of the components in the computer system 820. The I/O component 826A and/or the external I/O component 826B can comprise one or more human I/O devices, which enable a human user 812 to interact with the computer system 820 and/or one or more communications devices to enable a system user 812 to communicate with the computer system 820 using any type of communications link. To this extent, during execution by the computer system 820, the analysis program 830 can manage a set of interfaces (e.g., graphical user interface(s), application program interface, and/or the like) that enable human and/or system users 812 to interact with the analysis program 830. Furthermore, the analysis program 830 can manage (e.g., store, retrieve, create, manipulate, organize, present, etc.) the data, such as data 840, using any solution. Unless otherwise noted, the phrase “any solution” means any now known or later developed solution.

In any event, the computer system 820 can comprise one or more general purpose computing articles of manufacture (e.g., computing devices) capable of executing program code, such as the analysis program 830, installed thereon. As used herein, it is understood that “program code” means any collection of instructions, in any language, code or notation, that cause a computing device having an information processing capability to perform a particular function either directly or after any combination of the following: (a) conversion to another language, code or notation; (b) reproduction in a different material form; and/or (c) decompression. To this extent, the analysis program 830 can be embodied as any combination of system software and/or application software.

Furthermore, the analysis program 830 can be implemented using a set of modules 832. In this case, a module 832 can enable the computer system 820 to perform a set of tasks used by the analysis program 830, and can be separately developed and/or implemented apart from other portions of the analysis program 830. When the computer system 820 comprises multiple computing devices, each computing device can have only a portion of the analysis program 830 fixed thereon (e.g., one or more modules 832). However, it is understood that the computer system 820 and the analysis program 830 are only representative of various possible equivalent monitoring and/or control systems that may perform a process described herein with regard to the control unit, the main heating unit 100, the auxiliary heating unit 102, the in-situ-measurement unit 92, and the temperature sensor 32. To this extent, in other embodiments, the functionality provided by the computer system 820 and the analysis program 830 can be at least partially be implemented by one or more computing devices that include any combination of general and/or specific purpose hardware with or without program code. In each embodiment, the hardware and program code, if included, can be created using standard engineering and programming techniques, respectively. In another embodiment, the control unit 34 can be implemented without any computing device, e.g., using a closed loop circuit implementing a feedback control loop in which the outputs of one or more sensors are used as inputs to control the operation of the main heating unit 100, the auxiliary heating unit 102 and/or the in-situ measurement unit 92. Illustrative aspects of the invention are further described in conjunction with the computer system 820. However, it is understood that the functionality described in conjunction therewith can be implemented by any type of monitoring and/or control system.

Regardless, when the computer system 820 includes multiple computing devices, the computing devices can communicate over any type of communications link. Furthermore, while performing a process described herein, the computer system 820 can communicate with one or more other computer systems, such as the user 812, using any type of communications link. In either case, the communications link can comprise any combination of various types of wired and/or wireless links; comprise any combination of one or more types of networks; and/or utilize any combination of various types of transmission techniques and protocols.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. A system, comprising:
a wafer carrier;
a main heating unit configured to heat a region within the wafer carrier;
an auxiliary heating unit configured to support the main heating unit in heating the region of the wafer carrier;
at least one temperature sensor configured to sense a temperature of the region of the wafer carrier while being heated and generate signal representations of the temperature; and
a control unit configured to control heating of the wafer carrier by the main heating unit and the auxiliary heating unit as a function of the temperature at the region of wafer carrier, the control unit determining a temperature distribution over a surface of the region of the wafer carrier while heated by the main heating unit in accordance with the temperature signals, the control unit initiating operation of the auxiliary heating unit in response to determining that the temperature distribution over the surface of the region of the wafer carrier fails to satisfy a target temperature distribution.

2. The system of claim 1, wherein the control unit is further configured to specify a plurality of operating parameters for the auxiliary heating unit that are coordinated with the main heating unit to enable heating of the surface of the region of the wafer carrier to the target temperature distribution by both the main heating unit and the auxiliary heating unit.

3. The system of claim 2, wherein the control unit is further configured to monitor the temperature distribution over the surface of the region of the wafer carrier while heated by both the main heating unit and the auxiliary heating unit.

4. The system of claim 3, wherein the control unit is further configured to adjust at least one of the operating parameters for the auxiliary heating unit in response to determining that the temperature distribution over the surface of the region of the wafer carrier while heated by the main heating unit and the auxiliary heating unit is failing to satisfy the target temperature distribution.

5. The system of claim 2, wherein the plurality of operating parameters for the auxiliary heating unit comprise a radiation source intensity, a time duration of operating the radiation source, and a direction and a pattern of radiation generated from the radiation source towards the surface of the region of the wafer carrier.

6. The system of claim 1, wherein the auxiliary heating unit comprises a resistive heating element located underneath the surface of the region of the wafer carrier.

7. The system of claim 1, wherein the auxiliary heating unit comprises an infrared heating system.

8. The system of claim 7 wherein the infrared heating system comprises a set of heat lamps.

9. The system of claim 8, further comprising a plurality of reflectors each operating with a corresponding heat lamp to focus heating radiation generated therefrom to a targeted portion of the surface of the region of the wafer carrier, the focused heating radiation generated from each heat lamp and corresponding reflector collectively form a target heating profile of heating radiation that is directed to the surface of the region of the wafer carrier.

10. The system of claim 9, further comprising an intermediate heating element placed between the region of the wafer carrier and the set of heat lamps and the plurality of reflectors, wherein the set of heat lamps and the plurality of reflectors heat the intermediate heating element in accordance with the target heating profile of heating radiation, the intermediate heating element diffusively directing the target heating profile of heating radiation to the surface of the region of the wafer carrier.

11. The system of claim 1, wherein the auxiliary heating unit and the temperature sensor include an infrared emitter detector, wherein the infrared emitter detector operates periodically as an infrared emitter that directs infrared heating radiation to the surface of the region of the wafer carrier and periodically as an infrared detector that detects the temperature over the surface at the region of the wafer carrier and provides the signal representations of the temperature to the control unit, wherein the control unit is configured to adjust an infrared emission intensity of the infrared emitter detector and a time duration of operating the infrared emitter as a function of the temperature signals for obtaining the target temperature distribution.

12. A system for an epitaxial growth process of semiconductor layers, comprising:
a susceptor configured to support at least one wafer during the epitaxial growth process;
a showerhead element configured to release gases towards the susceptor for epitaxially growing the semiconductor layers on the wafer;
a main heating unit configured to heat a region of the susceptor supporting the wafer;
an auxiliary heating unit configured to support the main heating unit in heating the region of the susceptor;
at least one pyrometer configured to sense a temperature of a surface of the wafer supported by the susceptor while being heated and generate signal representations of the temperature; and
a control unit configured to control heating of the susceptor by the main heating unit and the auxiliary heating unit as a function of the temperature at the surface of the wafer, the control unit determining a temperature distribution over the surface of the wafer while the susceptor is heated by the main heating unit in accordance with the temperature signals generated from the pyrometer, the control unit initiating operation of the auxiliary heating unit along with an already powered main heating unit in response to determining that the temperature distribution over the surface of the wafer fails to satisfy a target temperature distribution, the control unit monitoring the temperature distribution over the surface of the wafer while the susceptor is heated by both the main heating unit and the auxiliary heating unit, and the control unit adjusting at least one of a plurality of operating parameters for the auxiliary heating unit in response to determining that the temperature distribution over the surface of the wafer while the susceptor is heated by the main heating unit and the auxiliary heating unit is failing to satisfy the target temperature distribution.

13. The system of claim 12, wherein the auxiliary heating unit comprises a focused heating infrared auxiliary source configured to direct infrared radiation over different areas of the surface of the wafer.

14. The system of claim 13, wherein the focused heating infrared auxiliary source comprises one of: at least one infrared laser, at least one infrared light emitting diode and combinations thereof.

15. The system of claim 14, wherein the focused heating infrared auxiliary source comprises at least two infrared lasers, the infrared lasers introducing lateral fluctuations to the semiconductor layers epitaxially grown on the wafer, the lateral fluctuations imparting temperature fluctuations laterally over the surface of the wafer.

16. The system of claim 15, wherein the lateral fluctuations comprise patterns of: grids of lines of varying thickness and intensity, wherein the lateral temperature fluctuations induce compositional fluctuations within the semiconductor layers epitaxially grown on the wafer through diffusion, and wherein the compositional fluctuations for the semiconductor layers varies as a function of a temperature and a diffusion rate at a region of the semiconductor layers having the lateral temperature fluctuations.

17. The system of claim 12, further comprising an in-situ measurement unit configured to obtain a plurality of measurements from the surface of the wafer supported by the susceptor during the epitaxial growth of the semiconductor layers.

18. The system of claim 17, wherein the in-situ measurement unit obtains one of photoluminescence and cathodoluminescence measurements and generates signal representations thereof to the control unit, the control unit determining a presence of any lateral inhomogeneity on the semiconductor layers during the epitaxial growth process.

19. The system of claim 17, wherein the in-situ measurement unit obtains wafer bowing measurements during the epitaxial growth process and generates signal representations to the control unit, wherein the control unit is configured to adjust the operation of the auxiliary heating unit to generate a heating radiation that imparts a predetermined amount bowing to the wafer, wherein the control unit adjusts the auxiliary heating unit as a function of the wafer bowing measurements.

20. A method, comprising:
heating a wafer on a wafer carrier with a main heating unit during an epitaxial growth process of semiconductor layers;
obtaining temperature measurements from a surface of the wafer while being heated;
determining a temperature distribution over the surface of the wafer while being heated by the main heating unit;
determining whether the temperature distribution over the surface of the wafer carrier satisfies a target temperature distribution;
initiating operation of an auxiliary heating unit to heat the wafer along with the main heating unit in response to determining that the temperature distribution over the surface of the wafer carrier fails to satisfy a target temperature distribution;
monitoring the temperature distribution over the surface of the wafer while the wafer is heated by both the main heating unit and the auxiliary heating unit; and
adjusting at least one of a plurality of operating parameters for the auxiliary heating unit in response to determining that the temperature distribution over the surface of the wafer while heated by the main heating unit and the auxiliary heating unit is failing to satisfy the target temperature distribution.
